(19) United States
(12) Patent Application Publication
(10) Pub. No.: US 2024/0071988 A1
(43) Pub. Date: Feb. 29, 2024

(54) METHOD FOR MANUFACTURING SEMICONDUCTOR STRUCTURE

(71) Applicant: UNITED MICROELECTRONICS CORP., Hsinchu (TW)

(72) Inventors: Kun-Ju LI, Tainan City (TW); Hsin-Jung LIU, Pingtung County (TW); Wei-Xin GAO, Tainan City (TW); Jhih-Yuan CHEN, Kaohsiung City (TW); Ang CHAN, Taipei City (TW); Chau-Chung HOU, Tainan City (TW)

(21) Appl. No.: 17/963,227

(22) Filed: Oct. 11, 2022

(30) Foreign Application Priority Data
Aug. 25, 2022 (TW) 111132016

(51) Int. Cl. H01L 23/00

(52) U.S. Cl. CPC H01L 24/80; H01L 24/03; H01L 24/05; H01L 2224/03452; H01L 2224/05624; H01L 2224/05647; H01L 2224/05657; H01L 2224/05666; H01L 2224/05676; H01L 2224/05681; H01L 2224/05686; H01L 2224/80379; H01L 2224/80895; H01L 2224/80896

(57) ABSTRACT

A method for manufacturing a semiconductor structure is provided. The method includes: providing a substrate and a dielectric layer on the substrate; forming a hole in the dielectric layer; forming an initial barrier material layer and a conductive layer on an upper surface of the dielectric layer and in the hole; removing part of the initial barrier material layer and part of the conductive layer to form a barrier material layer and a via element in the hole respectively and expose the upper surface of the dielectric layer. An upper surface of the barrier material layer is higher than the upper surface of the dielectric layer.

This application claims the benefit of Taiwan application Serial No. 111132016, filed Aug. 25, 2022, the subject matter of which is incorporated herein by reference.

### BACKGROUND

### Technical Field

The disclosure relates to a method for manufacturing a semiconductor structure, and more particularly to a method for manufacturing a three-dimensional semiconductor structure.

### Description of the Related Art

Three-dimensional integrated circuits (3DICs) are important technologies for advanced semiconductor manufacturing processes to achieve smaller package sizes and more functional integration. 3DICs use bonding technology to stack multiple semiconductor chips. Such technology can effectively use space and increase the number of components that can be accommodated per unit area. However, there are still several important issues unaddressed in the development of 3DICs, among which, how to reduce the bonding failure risk is a big concern.

It is desirable to provide an improved method for manufacturing a semiconductor structure, which can improve bonding quality effectively and reduce the occurrence of bonding failure.

### SUMMARY

The present disclosure relates to a method for manufacturing a semiconductor structure.

According to an embodiment of the present disclosure, a method for manufacturing a semiconductor structure is provided. The method includes: providing a substrate and a dielectric layer on the substrate; forming a hole in the dielectric layer; forming an initial barrier material layer and a conductive layer on an upper surface of the dielectric layer and in the hole; removing part of the initial barrier material layer and part of the conductive layer to form a barrier material layer and a via element in the hole respectively and expose the upper surface of the dielectric layer. An upper surface of the barrier material layer is higher than the upper surface of the dielectric layer.

According to an embodiment of the present disclosure, a method for manufacturing a semiconductor structure is provided. The method includes: forming a first semiconductor element; forming a second semiconductor element; bonding the upper surface of the first dielectric layer of the first semiconductor element to the upper surface of the second dielectric layer of the second semiconductor element. The step of forming the first semiconductor element includes providing a first substrate, a first dielectric layer on the first substrate, a first barrier material layer on the first dielectric layer, and a first via element on the first barrier material layer, wherein an upper surface of the first barrier material layer is higher than an upper surface of the first dielectric layer. The step of forming the second semiconductor element includes providing a second substrate, a second dielectric layer on the second substrate, a second barrier material layer on the second dielectric layer, and a second via element on the second barrier material layer, wherein an upper surface of the second barrier material layer is higher than an upper surface of the second dielectric layer.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIGS. 1-5 schematically illustrate a method for manufacturing a semiconductor structure according to an embodiment of the present disclosure.

FIGS. 6-8 schematically illustrate a method for manufacturing a semiconductor structure according to an embodiment of the present disclosure.

### DETAILED DESCRIPTION

The illustrations may not be necessarily drawn to scale, and there may be other embodiments of the present disclosure which are not specifically illustrated. Thus, the specification and the drawings are to be regard as an illustrative sense rather than a restrictive sense. Moreover, the descriptions disclosed in the embodiments of the disclosure such as detailed construction, manufacturing steps and material selections are for illustration only, not for limiting the scope of protection of the disclosure. The steps and elements in details of the embodiments could be modified or changed according to the actual needs of the practical applications. The disclosure is not limited to the descriptions of the embodiments. The illustration uses the same/similar symbols to indicate the same/similar elements.

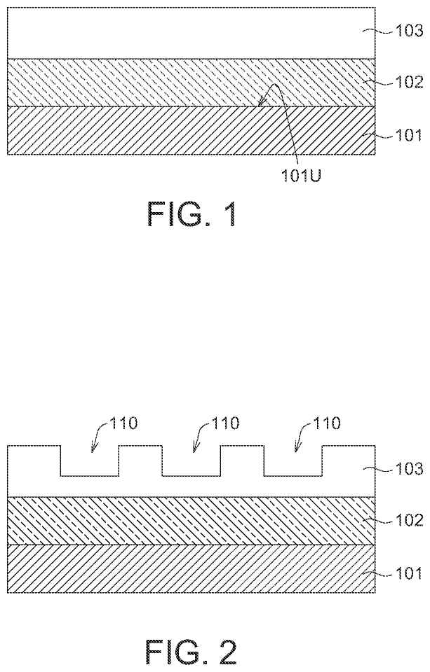

FIGS. 1-5 schematically illustrate a method for manufacturing a semiconductor structure according to an embodiment of the present disclosure.

Referring to FIG. 1, a substrate 101, a device layer 102 and a dielectric layer 103 are provided. The device layer 102 and the dielectric layer 103 are on an upper surface 101U of the substrate 101. The device layer 102 is between the dielectric layer 103 and the substrate 101. The substrate 101 may be a semiconductor substrate, such as a silicon (Si) substrate, or may be a SOI (silicon on insulator) substrate. In an embodiment, the substrate 101 may include a multilayer structure. The device layer 102 may include at least one semiconductor device, such as a transistor, capacitor, resistor, other active/passive semiconductor device, microelectronic/micromechanical structures, or any combination thereof. The dielectric layer 103 may include a dielectric material, such as silicon oxide (SiOₓ), silicon nitride (SiNₓ), silicon carbonitride (SiCₓN_{y}), etc.

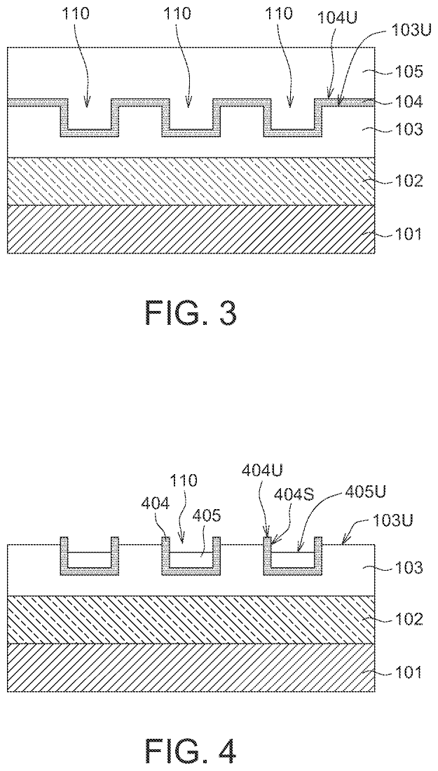

Referring to FIG. 2, holes 110 are formed in the dielectric layer 103. In an embodiment, the holes 110 are formed by removing part of the dielectric layer 103 by an etching process, such as a wet etching process or a dry etching process. Referring to FIG. 3, an initial barrier material layer 104 and a conductive layer 105 are formed on an upper surface 103U of the dielectric layer 103 and in the holes 110. The conductive layer 103 may be formed on an upper surface 104U of the initial barrier material layer 104. In an embodiment, the initial barrier material layer 104 is formed on the upper surface 103U of the dielectric layer 103 and lining the holes 110 by a deposition process, such as a chemical vapor deposition (CVD) process. The conductive layer 105 may fill the remaining space of the holes 110 and be formed on the upper surface 104U of the initial barrier material layer 104 by a deposition process, such as a chemical vapor deposition process. The initial barrier material layer 104 may include a metal barrier material, such as tantalum (Ta), tantalum nitride (TaN), cobalt (Co), ruthenium (Ru), titanium (Ti), titanium nitride (TiN), etc. The conductive layer 105 may include a conductive material, such as copper (Cu), aluminum (Al), etc.

Referring to FIG. 4, part of the initial barrier material layer 104 and part of the conductive layer 105 are moved to form a barrier material layer 404 and via elements 405. The upper surface 103U of the dielectric layer 103 is exposed. In an embodiment, part of the initial barrier material layer 104 and part of the conductive layer 105 on the upper surface 103U of the dielectric layer 103 are removed by a chemical-mechanical planarization (CMP) process or other suitable etching processes, and part of the initial barrier material layer 104 and part of the conductive layer 105 in the holes 110 are remained. The part of the conductive layer 105 in the holes 110 can be defined as the via elements 405. The via elements 405 may be on the barrier material layer 404. The barrier material layer 404 may be between the via elements 405 and the dielectric layer 103. In this step, as shown in FIG. 4, an upper surface 404U of the barrier material layer 404 is higher than the upper surface 103U of the dielectric layer 103 in a longitudinal direction. The upper surface 404U of the barrier material layer 404 may be higher than an upper surface 405U of the via element 405 in the longitudinal direction. The upper surface 103U of the dielectric layer 103 may be higher than the upper surface 405U of the via element 405 in the longitudinal direction. For example, the longitudinal direction is the normal direction of the upper surface 103U of the dielectric layer 103. The barrier material layer 404 has a sidewall 404S connected between the upper surface 404U of the barrier material layer 404 and the upper surface 405U of the via element 405.

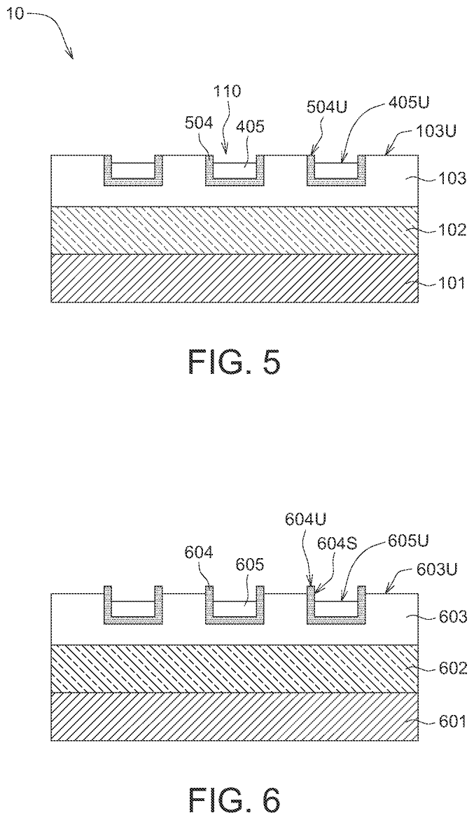

Referring to FIG. 5, part of the barrier material layer 404 is removed to form a barrier layer 504 in the hole 110. In an embodiment, part of the barrier material layer 404 higher than the upper surface 103U of the dielectric layer 103 is removed by a chemical-mechanical planarization process or other suitable etching processes, and part of the barrier material layer 404 lower than the upper surface 103U of the dielectric layer 103 is remained. The part of the barrier material layer 404 lower than the upper surface 103U of the dielectric layer 103 can be defined as the barrier layer 504. In this step, an upper surface 504U of the barrier layer 504 is coplanar with the upper surface 103U of the dielectric layer 103. The upper surface 504U of the barrier layer 504 may be higher than the upper surface 405U of the via element 405 in the longitudinal direction.

In an embodiment, a semiconductor element 10 may be provided through the method schematically illustrated in FIGS. 1-5.

In an embodiment, the method for manufacturing a semiconductor structure of the present disclosure may further include steps shown in FIGS. 6-8.

Referring to FIG. 6, a substrate 601, a dielectric layer 603 on the substrate 601, a device layer 602 between the substrate 601 and the dielectric layer 603, a barrier material layer 604 on the dielectric layer 603, and via elements 605 on the barrier material layer 604 are provided. In an embodiment, the structure shown in FIG. 6 can be formed through the manufacturing steps described with reference to FIGS. 1-4. In this step, an upper surface 604U of the barrier material layer 604 is higher than an upper surface 603U of the dielectric layer 603 in a longitudinal direction. The upper surface 604U of the barrier material layer 604 may be higher than an upper surface 605U of the via element 605 in the longitudinal direction. The upper surface 603U of the dielectric layer 603 may be higher than the upper surface 605U of the via element 605 in the longitudinal direction. For example, the longitudinal direction is the normal direction of the upper surface 603U of the dielectric layer 603. The barrier material layer 604 has a sidewall 604S connected between the upper surface 604U of the barrier material layer 604 and the upper surface 605U of the via element 605. The substrate 601 may be similar to the substrate 101 shown in FIGS. 1-4. The device layer 602 may be similar to the device layer 102 shown in FIGS. 1-4. The dielectric layer 603 may be similar to the dielectric layer 103 shown in FIGS. 1-4. The barrier material layer 604 may be similar to the barrier material layer 404 shown in FIG. 4. The via element 605 may be similar to the via element 405 shown in FIG. 4.

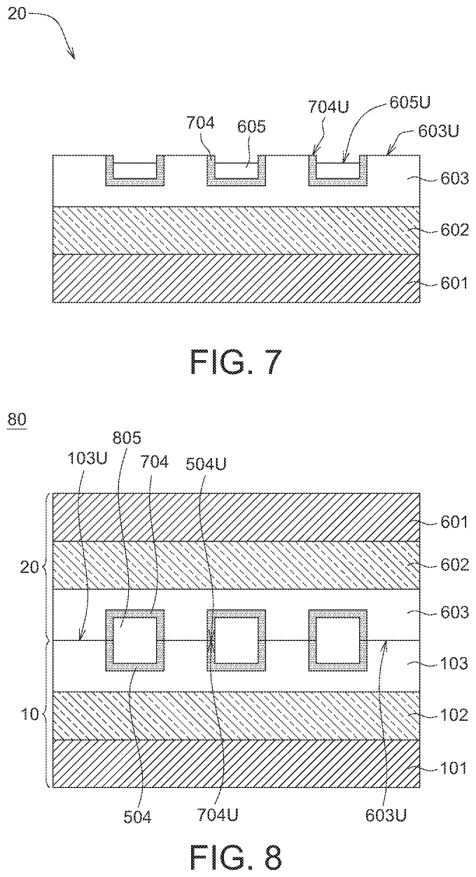

Referring to FIG. 7, part of the barrier material layer 604 is moved to form a barrier layer 704. In an embodiment, part of the barrier material layer 604 higher than the upper surface 603U of the dielectric layer 603 is removed by a chemical-mechanical planarization process or other suitable etching processes, and part of the barrier material layer 604 lower than the upper surface 603U of the dielectric layer 603 is remained. The part of the barrier material layer 604 lower than the upper surface 603U of the dielectric layer 603 can be defined as the barrier layer 704. In this step, an upper surface 704U of the barrier layer 704 is coplanar with the upper surface 603U of the dielectric layer 603. The upper surface 704U of the barrier layer 704 may be higher than the upper surface 605U of the via element 605 in the longitudinal direction. In an embodiment, a semiconductor element 20 may be provided through the method schematically illustrated in FIGS. 6-7. The steps for manufacturing the semiconductor element 10 and the semiconductor element 20 may be performed simultaneously, or may be performed sequentially.

Referring to FIG. 8, the semiconductor element 10 is bonded to the semiconductor element 20 to form a semiconductor structure 80 after the formation of the semiconductor element 10 and the semiconductor element 20. In an embodiment, the method for bonding the semiconductor element 10 to the semiconductor element 20 may include the following steps: the semiconductor element 10 and the semiconductor element 20 are oriented such that the upper surface 103U of the dielectric layer 103 of the semiconductor element 10 faces the upper surface 603U of the dielectric layer 603 of the semiconductor element 20; a force perpendicular to the upper surface 103U of the dielectric layer 103 and the upper surface 603U of the dielectric layer 603 is applied to the semiconductor element 10 and the semiconductor element 20 such that the upper surface 103U of the dielectric layer 103 of the semiconductor element 10 contacts and be bonded to the upper surface 603U of the dielectric layer 603 of the semiconductor element 20 and the upper surface 704U of the barrier layer 704 of the semiconductor element 20 is bonded to the upper surface 504U of the barrier layer 504 of the semiconductor element 10. In an embodiment, the method for manufacturing a semiconductor structure of the present disclosure may further include an annealing process to re-grow and bond the via element 405 of the semiconductor element 10 and the via element 605 of the semiconductor element 20 to form a via element 805. In this embodiment, bonding of the semiconductor element 10 and the semiconductor element 20 includes a hybrid bonding. That is, bonding of the semiconductor element 10 and the semiconductor element 20 involves at least two types of bonding, such as metal-to-metal bonding and nonmetal-to-nonmetal bonding.

In a comparative example, the method for manufacturing a semiconductor structure removes part of the initial barrier material layer and part of the conductive layer to form the barrier layer and the via element directly instead of including a step of making the upper surface of the barrier material layer higher than the upper surface of the dielectric layer. Such step would result in a rounding corner or a sloping surface at the connection between the dielectric layer and the barrier layer and/or a sloped upper surface of the barrier layer, and thus the bonding surface area and the bonding quality decrease.

According to the embodiments described above, the method for manufacturing a semiconductor structure provided by the present disclosure avoids the formation of rounding corner or sloping surface at the connection between the dielectric layer and the barrier layer and/or avoids the formation of sloped upper surface of the barrier layer by making the upper surface of the barrier material layer higher than the upper surface of the dielectric layer. A sufficient bonding surface area can be ensured, the bonding quality can be improved effectively, and the occurrence of bonding failure can be reduced.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A method for manufacturing a semiconductor structure, comprising:
providing a substrate and a dielectric layer on the substrate;
forming a hole in the dielectric layer;
forming an initial barrier material layer and a conductive layer on an upper surface of the dielectric layer and in the hole; and
removing part of the initial barrier material layer and part of the conductive layer to form a barrier material layer and a via element in the hole respectively and expose the upper surface of the dielectric layer,
wherein an upper surface of the barrier material layer is higher than the upper surface of the dielectric layer.

2. The method according to claim 1, wherein the upper surface of the barrier material layer is higher than an upper surface of the via element.

3. The method according to claim 2, wherein the upper surface of the dielectric layer is higher than the upper surface of the via element.

4. The method according to claim 2, wherein the barrier material layer has a sidewall connected between the upper surface of the barrier material layer and the upper surface of the via element.

5. The method according to claim 1, further comprising:
removing part of the barrier material layer to form a barrier layer in the hole, wherein an upper surface of the barrier layer is coplanar with the upper surface of the dielectric layer.

6. The method according to claim 5, wherein the upper surface of the barrier layer is higher than an upper surface of the via element.

7. A method for manufacturing a semiconductor structure, comprising:
forming a first semiconductor element, comprising:
providing a first substrate, a first dielectric layer on the first substrate, a first barrier material layer on the first dielectric layer, and a first via element on the first barrier material layer, wherein an upper surface of the first barrier material layer is higher than an upper surface of the first dielectric layer;
forming a second semiconductor element, comprising:
providing a second substrate, a second dielectric layer on the second substrate, a second barrier material layer on the second dielectric layer, and a second via element on the second barrier material layer, wherein an upper surface of the second barrier material layer is higher than an upper surface of the second dielectric layer; and
bonding the upper surface of the first dielectric layer of the first semiconductor element to the upper surface of the second dielectric layer of the second semiconductor element.

8. The method according to claim 7, further comprising:
removing part of the first barrier material layer to form a first barrier layer, wherein an upper surface of the first barrier layer is coplanar with the upper surface of the first dielectric layer; and
removing part of the second barrier material layer to form a second barrier layer, wherein an upper surface of the second barrier layer is coplanar with the upper surface of the second dielectric layer.

9. The method according to claim 8, further comprising:
bonding the upper surface of the first barrier layer to the upper surface of the second barrier layer.

10. The method according to claim 7, wherein the upper surface of the first barrier material layer is higher than an upper surface of the first via element, the first barrier material layer has a sidewall connected between the upper surface of the first barrier material layer and the upper surface of the first via element.
